(19) United States
(12) Patent Application Publication
(10) Pub. No.: US 2010/0258797 A1
(43) Pub. Date: Oct. 14, 2010

(54) ORGANIC ELECTROLUMINESCENT DEVICE AND METHOD FOR MANUFACTURING THE SAME

(75) Inventors: Shinya YAMAMOTO, Fukuoka (JP); Naoto MATSUO, Fukuoka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/759,017

(22) Filed: Apr. 13, 2010

(30) Foreign Application Priority Data
Apr. 13, 2009 (JP) 2009-096856
Oct. 16, 2009 (JP) 2009-239022

(51) Int. Cl. H01L 33/28; H01L 21/36; B32B 37/06; B32B 38/00

(52) U.S. Cl. 257/43; 438/46; 156/272.2; 156/151; 257/E33.019; 257/E21.461

(57) ABSTRACT

An organic electroluminescent device is provided, including at least one light emitting layer 5 composed of an organic material between a transparent electrode and a counter electrode, wherein the organic electroluminescent device includes an electron injection layer 6 previously provided on the organic layer side of the counter electrode which is contact disposed in a solid plate form on the organic layer and heat and pressure formed, and the electron injection layer 6 is constituted of a metal oxide. According to this configuration, it is possible to heat soften the counter electrode in a fixed plate form and join it, and it is possible to inexpensively manufacture the organic electroluminescent device 1 with ease.

### BACKGROUND

1. Field of the Invention

The present invention relates to an organic electroluminescent device and a method for manufacturing the organic device. In particular, the invention relates to an organic electroluminescent device which is an electroluminescent device to be driven over a wide luminance range of from a low luminance adopted for display devices and electronic appliances using an organic luminescent device as a light source to a high luminance for light source applications and the like and to a method for manufacturing the same.

2. Description of the Related Art

Electroluminescent devices are a light emitting device utilizing electroluminescence of a solid fluorescent substance, and inorganic electroluminescent devices using an inorganic material as a luminous body are put into practical use. At present, the electroluminescent devices are applied and spread to a backlight of a liquid crystal display, a flat panel display (FPD) and the like. However, the inorganic electroluminescent devices involve a number of such problems that a voltage required for light emission is high as 100 V or more; that blue light emission is difficult; and that full-coloration by the three primary colors of RGB is difficult.

On the other hand, attention has also been paid to studies regarding electroluminescent devices using an organic material from of old, and a variety of investigations have been made. However, a full-scale study for practical implementation has not developed because the luminous efficiency is very poor. However, in 1987, an organic EL device having a laminated structure of a function-separated type in which an organic material constituting a light emitting layer is separated into two layers of a hole transport layer and a light emitting layer was proposed by Messrs. C. W. Tang, et al. of Eastman Kodak Company, and it was clarified that in spite of a low voltage of not more than 10 V, a high luminance of 1,000 cd/m² or more is obtained (see Non-Patent Document 1).

Since then, with respect to the organic electroluminescent device, studies regarding an organic electroluminescent device having the same laminated structure of a function-separated type are eagerly carried out even now. In particular, as to realization of high efficiency and long life which are indispensable to practical implementation of the organic electroluminescent device, a sufficient result is obtained. In recent years, displays using an organic electroluminescent device or the like have been realized.

FIG. 7 is a sectional view showing a structure of a conventional organic electroluminescent device. A structure of a conventional general organic electroluminescent device is hereinafter described with reference to FIG. 7.

As shown in FIG. 7, an organic electroluminescent device 111 is, for example, provided with an anode 113 composed of a transparent conductive film such as ITO, which is formed on a glass substrate 112 by a sputtering method, a resistance heating vapor deposition method or the like; a hole transport layer 114 made of N,N′-dipehnyl-N,N′-bis(3-methylphenyl)-1,1′-diphenyl-4,4′-diamine (hereinafter abbreviated as “TPD”), etc., which is formed on the anode 113 by the same resistance heating vapor deposition method or the like; an organic material layer 115 made of 8-hydroxyquinoline aluminum (hereinafter abbreviated as “Alq₃”), etc., which is formed on the hole transport layer 114 by a resistance heating vapor deposition method or the like; and a cathode 117 composed of a metal film having a thickness of from about 100 to 300 nm, which is formed on the organic material layer 115 by a resistance heating vapor deposition method or the like.

The hole transport layer 114 and the organic material layer 115 are comprehensively referred to simply as a light emitting layer 116 for the sake of convenience. In that case, the light emitting layer 116 may include, in addition to the hole transport layer 114 and the organic material layer 115, a hole injection layer, an electron injection layer, an electron transport layer and an electron blocking layer (all not shown) and so on.

Furthermore, in the EL device having the foregoing structure, for the purpose of preventing deterioration to be caused due to influences of moisture, etc., a sealing part 118 constituted of, for example, a glass having a bathtub shape is provided so as to cover the entire surface of the organic electroluminescent device 111, and its outer peripheral part is bonded to the glass substrate 112 or the like with an adhesive. The following description follows this example, too.

However, though in a number of organic devices represented by the organic electroluminescent device 111, a high vacuum thin film fabrication technology such as a vapor deposition method or a sputtering method has been adopted, in recent years, for the purpose of simplifying the process, there has been developed and realized a coating process of a hole injection layer or an organic material layer by a spin coating method, an inkjet method or a printing method such as screen printing or flexo printing. However, in the manufacturing process, there is still no technique in the electrode formation as a substitute of the high-vacuum vapor deposition or sputtering method, and therefore, an enhancement of the productivity is hindered.

On the other hand, Patent Document 1 proposes that in an organic electroluminescent device and an organic device, the productivity and cost are improved by melting an electrode material having a melting point of from 100 to 250° C. and bringing the molten electrode material into contact with an organic layer to achieve melt bonding.

However, according to this method, it is necessary to achieve the deposition by previously bringing a cathode metal in a molten state into direct contact with an organic layer, and therefore, it was difficult to control the temperature of the electrode material or organic layer in itself for the purpose of keeping the molten state. Furthermore, for the purpose of making an electrical resistance value sufficiently small to make a current density uniform, when a thickness of the formed electrode is made large, there was a concern that the electrode caused aggregation in the molten state due to an intermolecular force acting between molecules of a liquid or the like, whereby lack of uniformity in the thickness is caused.
[Non-Patent Document 1] C. W. Tang and S. A. Vanslyke, Appl. Phys. Lett. (U.S.A.), Volume 51, 1987, page 913
[Patent Document 1] JP-A-2005-277340

### SUMMARY

An object of the invention is to provide a method for manufacturing a simplified organic device without relying upon a high vacuum thin film fabrication technology such as a vapor deposition method or a sputtering method, an organic electroluminescent device prepared therefrom and an electronic appliance using it as a light source.

In particular, in an organic electroluminescent device, a structure or a manufacturing step for realizing surface light emission is simple, and therefore, it is said that applications such as light emitting apparatus mounted with an organic electroluminescent device, backlight chiefly for spontaneous light emission type displays or liquid crystal displays, illumination of a surface light emission type or exposure apparatus applying an organic electroluminescent device as a light source are advantageous for realizing a low cost.

However, in view of the fact that it is necessary to inject a large charge for the purpose of obtaining a large quantity of light, there was also involved such a problem that the heat generation following the charge transfer accelerates the deterioration of an organic material and reduces the life.

For those reasons, though thickening of an electrode is an extremely useful measure, the conventional high vacuum thin film fabrication technology such as a vapor deposition method or a sputtering method involved such problems that the deposition rate is low and that the production cost is high. Also, in order to obtain a large quantity of light, there was involved such a problem that the life is short because the luminous efficiency is low, and the driving voltage is high.

In view of the foregoing problems, the invention has been made. The invention is concerned with an organic electroluminescent device comprising at least one light emitting layer made of an organic material between a transparent electrode and a counter electrode, wherein the organic electroluminescent device includes an electron injection layer previously provided on the organic layer side of the counter electrode which is contact disposed in a solid plate form on the organic layer and heat and pressure formed, and the electron injection layer is constituted of a metal oxide.

According to this configuration, it is possible to heat soften the counter electrode in a fixed plate form and join it, and it is possible to inexpensively manufacture an organic electroluminescent device with ease.

At that time, it is possible to enhance the registration of electrode disposition with ease by using a holding plate for holding the solid plate electrode material, if desired.

Also, even when the shape on the organic layer side is a complicated shape including a difference in level, it is possible to provide a manufacturing method free from the generation of junction defect and an organic electroluminescent device by using a material with high rigidity for the holding plate and pressurizing it.

Furthermore, it is easy to inject an electron into the organic layer by providing the electron injection layer, whereby it becomes possible to enhance the luminous efficiency of the organic electroluminescent device. Also, in view of the fact that it is easy to inject an electron from the cathode into the organic layer, the driving voltage is lowered, whereby it becomes possible to reduce a consumed power.

Also, in view of the fact that the uniformity of electron injection from the cathode into the organic layer within the organic electroluminescent device plane is enhanced, it is possible to suppress the light emission unevenness within the plane, and it is possible to obtain uniform light emission.

Also, in view of the fact that the electron injection layer is constituted of a metal oxide, the organic electroluminescent device is inert against oxygen, moisture or the like, namely, influences of reactive materials in the inside and outside of the organic electroluminescent device can be reduced, whereby it becomes possible to obtain a long-term electron injection characteristic. Also, before the counter electrode is joined with the organic layer, the electron injection layer can be previously formed on the surface of the resistance electrode, whereby it becomes possible to prevent damage which is a cause of deterioration of the organic layer due to the formation of the electron injection layer. As a result, it is possible to provide an organic electroluminescent device with a long life.

Also, the invention is concerned with the foregoing organic electroluminescent device, wherein the metal oxide is zinc oxide (ZnO) and titanium oxide (TiO₂).

According to this configuration, it is possible to impart to the electrode an electron injection characteristic into an organic layer exceeding an electron injection characteristic obtained by only a counter electrode in a solid plate form, and it is possible to enhance the luminous efficiency of the organic electroluminescent device.

Also, since these metal oxides are small in specific resistance while they are an oxide, an electric field to be impressed between the both electrodes is impressed to the light emitting layer as it is without causing a voltage drop, whereby it becomes possible to obtain a high-luminance characteristic.

Also, since these metal oxides have an electron injection function, an electron transport function and a hole blocking function, favorable electron injection can be realized, and a light emitting region which is a region where a hole and an electron are recombined with each other in the organic layer can be controlled.

In consequence, for example, it is possible to enhance the device efficiency and further to enhance the device life by controlling the light emitting region so as to be located on the center of the light emitting layer, an aspect of which has hitherto been not easy.

Also, in view of the fact that these metal oxides are a stable material, the metal oxides do not require special equipment, are easy for handling at the time of preparation of a device and are a general material as an oxide semiconductor material. Therefore, it is possible to provide an inexpensive organic electroluminescent device.

Also, the invention is concerned with the foregoing organic electroluminescent device, wherein the counter electrode in a solid plate form has a thickness of 5 μm or more.

According to this configuration, it is possible to make the deformation to be caused due to softening of the electrode material large, and not only follow-up properties against recesses and projections on the surface of the organic layer can be ensured, but a resistance value as the electrode can be made small. Therefore, the heat generation following the charge transfer can be greatly lowered, and damage to the organic layer due to the heat generation can be greatly lowered.

Also, in view of the fact that not only the heat generation following the charge transfer can be greatly reduced, but heat dissipation properties are enhanced due to an increase of the volume of the electrode, it is possible to impress a large current to the inside of the device as compared with that in an organic electroluminescent device having an electrode thinner than the electrode of the invention, for example, an electrode having a thickness of several hundred nm, and it is possible to increase the luminous luminance.

Furthermore, in the view of the fact that a barrier performance against an external gas is tremendously enhanced, a protective characteristic of the organic device is also greatly enhanced.

Also, the invention is concerned with the foregoing organic electroluminescent device, wherein the electron injection layer has a film thickness of from 10 angstroms to 200 angstroms.

According to this configuration, it is possible to impart to the electrode an electron injection characteristic into the organic layer, and it is possible to enhance the luminous efficiency.

Also, it is possible to keep a bond strength in achieving bonding by heat softening of the counter electrode in a solid plate form having the electron injection layer onto the organic layer. When the film thickness of the electron injection layer is less than 10 angstroms, the amount of the material having an electron injection function is so small that a sufficient electron injection characteristic cannot be imparted to the counter electrode.

On the other hand, when the film thickness of the electron injection layer exceeds 200 angstroms, the electron injection layer is so thick that bonding of the counter electrode in a solid plate form to the organic layer is disturbed.

Also, transparency of the electron injection layer is impaired.

Also, the invention is concerned with the foregoing organic electroluminescent device, wherein the electron injection layer has a film thickness of from 60 angstroms to 100 angstroms.

According to this configuration, it is possible to impart to the electrode an electron injection characteristic into the organic layer, and it is possible to enhance the luminous efficiency.

Also, it is possible to keep a bond strength in achieving bonding by heat softening of the counter electrode in a solid plate form having the electron injection layer onto the organic layer. In addition such an action, when the film thickness of the electron injection layer falls within the foregoing range, a more enhancement of the luminous efficiency is obtainable.

Also, in view of the fact that the electron injection is uniformly performed within the plane of the device, the in-plane distribution of light emission is made uniform, and more uniform light emission is obtainable. As a result, it becomes possible to provide an organic electroluminescent device with a long life.

Also, the invention is concerned with the foregoing organic electroluminescent device, wherein the electron injection layer has a transmittance of 80% or more relative to light emitted from the organic layer and light passing through the organic layer.

According to this configuration, it is possible to make light emitted in the organic layer and light which has passed through the organic layer to reach the electron injection layer reach the counter electrode without being absorbed in the electron injection layer and be further reflected by the counter electrode and again emitted outside the organic electroluminescent device through the electron injection layer, the organic layer, the transparent electrode and the substrate; and it is possible to suppress a reduction of the light emission emitted from the organic layer.

Also, the invention is concerned with the foregoing organic electroluminescent device, wherein the electron injection layer has a specific resistance of not more than 10,000 Ωm.

According to this configuration, a voltage drop to be caused due to the electron injection layer per se, which is made of a metal oxide, is small, and it is possible to achieve high-luminance light emission.

Also, the invention is concerned with the foregoing organic electroluminescent device, wherein the electron injection layer has a work function of from 4.0 eV to 6.0 eV.

According to this configuration, a favorable ohmic contact can be formed. When the work function of the electron injection layer is less than 4.0 eV, the reactivity of the electron injection layer material tends to become high; the reduction of influences of the reactive material, an aspect of which is a characteristic feature of the invention, is difficultly achieved; and favorable light emission is not obtainable. On the other hand, when the work function of the electron injection layer exceeds 6.0 eV, a difference in the work function from the cathode which is the counter electrode becomes large, and therefore, favorable light emission is not obtainable.

Also, the invention is concerned with the foregoing organic electroluminescent device, wherein an average surface roughness Ra of the surface of the counter electrode on which the electron injection layer is provided is thicker than a film thickness of the electron injection layer.

According to this configuration, all of recesses and projections of the surface of the counter electrode are not covered by the metal oxide as a material of the electron injection layer; it is possible to prevent a lowering of the bond strength between the organic layer and the counter layer from occurring; and it is possible to secure the reliability of the counter electrode over a long period of time.

Also, the invention is concerned with the foregoing organic electroluminescent device, wherein an average surface roughness Ra of the surface of the counter electrode on which the electron injection layer is provided is smaller than the total sum of a film thickness of the organic layer existing between the two electrodes counterpart to each other.

According to this configuration, when the counter electrode in a solid plate form is brought into contact with the organic layer, not only it is possible to reduce damage to the organic layer, but it is possible to form an electrode without generating a short circuit between the electrodes.

Also, the uniformity of the film thickness of the organic layer is not impaired at the time of forming an electrode, and the electric field concentration is prevented from occurring, whereby uniform light emission is obtainable.

Also, the invention is concerned with the foregoing electroluminescent device, wherein an average surface roughness Ra of the surface of the counter electrode on which the electron injection layer is provided is from 20 nm to 300 nm.

According to this configuration, it is possible to suppress a lowering of the bond strength between the counter layer and the organic layer from occurring, and it is possible to prevent a short circuit between the electrodes. When the average surface roughness Ra of the counter electrode is less than 20 nm, in forming the electron injection layer, the surface of the counter electrode is completely covered by the electron injection material, and the bond strength to the organic layer is lowered.

On the other hand, when the average surface roughness Ra of the counter electrode exceeds 300 nm, there is a possibility that when the counter electrode is brought into contact with the organic layer, the counter electrode pierces through the organic layer, thereby generating a short circuit between the electrodes.

Also, the invention is concerned with the foregoing organic electroluminescent device, wherein the at least one organic layer includes a layer made of a conductive polymer material. In the conductive polymer material, long molecular chains are complexly entangled with each other, and even when exposed to a high-temperature environment, the crystallization is not advanced as compared with low molecular weight materials which are used for general electroluminescent devices. Therefore, the conductive polymer material is excellent in heat resistance.

According to this configuration, when the counter electrode is brought into contact with the organic layer in a fixed plate form and heat softened, it is possible to reduce the deterioration of the organic layer, and it is possible to enhance the reliability to heat.

Also, because of excellent heat resistance, it is possible to relieve restrictions of a heating condition in a heat softening step of the counter electrode. Also, when the counter electrode in a solid plate form is brought into contact with the organic layer, the conductive polymer material bears a role of a binder, whereby it becomes possible to prevent a short circuit between the electrodes.

Also, the invention is concerned with the foregoing organic electroluminescent device, wherein the at least one organic layer is deposited by a coating method.

According to this configuration, it is possible to easily manufacture an inexpensive organic device with a large area.

By contact disposing the electrode in a fixed plate form on the organic material layer, the electrode part is fixed in a solid shape, and therefore, not only handling is easy, but it is possible to form only a necessary portion, thereby making it easy to prepare an arbitrary complicated shape.

Also, by performing heat softening, junction with the organic layer formed on the electrode or the counter electrode having recesses and projections such as an insulating layer is excellent, and by applying an appropriate load, it is possible to enhance the junction precision.

Also, according to the invention, the electrode is solid, and therefore, it is possible to previously control the film thickness of the electrode. Also, the current density is made uniform, and therefore, it is also possible to prepare a non-uniform electrode having a partially different film thickness, if desired. Also, it is possible to realize uniform light emission with a high luminance even in large areas as in, for example, a backlight, a light source or the like.

Also, according to the invention, the electrode is not made in a molten state, and therefore, it is possible to prepare an extremely thick electrode within a short period of time without generating aggregation due to an intermolecular force generated when the fluidity is high.

Furthermore, when the film thickness of the electrode is thick, the covering effect relative to the organic layer is increased, and barrier properties relative to a material to be damaged by moisture, oxygen, etc. from the outside of the organic layer or the like are revealed. Also, by devising the covering shape, it is possible to impart an effect as a sealing layer.

Also, in view of the fact that the electrode is solid, by partially changing the composition of the electrode material to provide a portion having a large charge mobility relative to the organic layer and high junction properties and a portion having high charge conductivity, it is possible to tremendously enhance the efficiency as an organic device. At that time, by increasing the surface area of the electrode within the range where scattering of the electric field density is not generated, it is possible to enhance the efficiency of charge injection.

Also, by disposing an inorganic oxide layer between the organic layer and the cathode, it is easy to inject an electron into the organic layer, and it is possible to achieve an enhancement of the luminous efficiency of the organic electroluminescent device, a lowering of the driving voltage and a reduction of the consumed power. The organic electroluminescent device is inert against oxygen, moisture, etc., and influences of reactive materials can be reduced, whereby it becomes possible to obtain a long-term electron injection characteristic; and it is possible to form the electron injection layer without damaging the organic layer. As a result, it is possible to provide an organic electroluminescent device with a long life.

Also, a carrier balance can be adjusted, and for example, the light emission is realized on a center of the light emitting layer, whereby the breakage of the interface can be suppressed. Also, thermal deactivation of an exciton can be suppressed, and the organic electroluminescent device stably works and is excellent in a life characteristic.

### BRIEF DESCRIPTION OF THE DRAWINGS

FIG. 1 is a sectional view showing a structure of an organic electroluminescent device according to an embodiment of the invention.

FIG. 2 is an explanatory view of dependency of luminous efficiency of an organic electroluminescent device according to Example 1 of the invention upon a film thickness of an electron injection layer.

FIG. 3 is a view showing a light emitting surface and a light emitting section of an organic electroluminescent device according to Example 1 of the invention.

FIG. 4 is a graph showing luminous efficiency of an electron injection layer of an organic electroluminescent device according to the Examples of the invention in a deposition method.

FIG. 5A is an electron microscopic photograph of the surface of a counter electrode not subjected to a plating treatment, which is enlarged by a factor of 10,000; FIG. 5B is an electron microscopic photograph of the surface of FIG. 5A further enlarged by a factor of 5; FIG. 5C is an electron microscopic photograph of the surface of a counter electrode having been subjected to a zinc electroplating treatment for 5 seconds, which is enlarged by a factor of 10,000; FIG. 5D is an electron microscopic photograph of the surface of FIG. 5C further enlarged by a factor of 5; FIG. 5E is an electron microscopic photograph of the surface of a counter electrode having been subjected to a zinc electroplating treatment for 10 seconds, which is enlarged by a factor of 10,000; FIG. 5F is an electron microscopic photograph of the surface of FIG. 5E further enlarged by a factor of 5; FIG. 5G is an electron microscopic photograph of the surface of a counter electrode having been subjected to a zinc electroplating treatment for 20 seconds, which is enlarged by a factor of 10,000; and FIG. 5H is an electron microscopic photograph of the surface of FIG. 5G further enlarged by a factor of 5.

FIG. 6 is a graph obtained by plotting diameters of particles deposited on the surface of a counter electrode versus an electroplating treatment time.

FIG. 7 is a sectional view showing a structure of a conventional organic electroluminescent device.

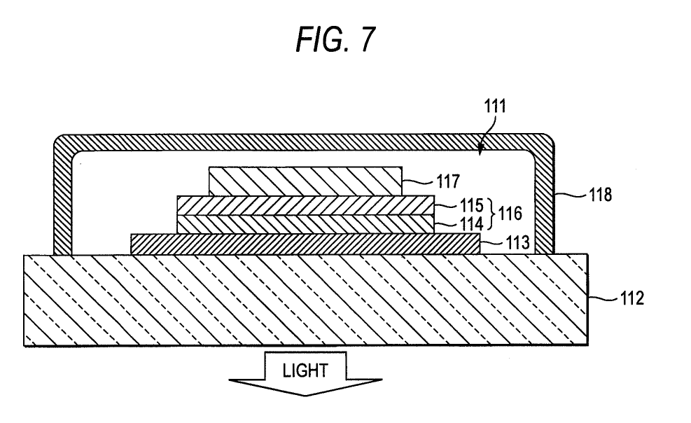

### DETAILED DESCRIPTION

An embodiment of the invention is hereunder described with reference to the accompanying drawings.

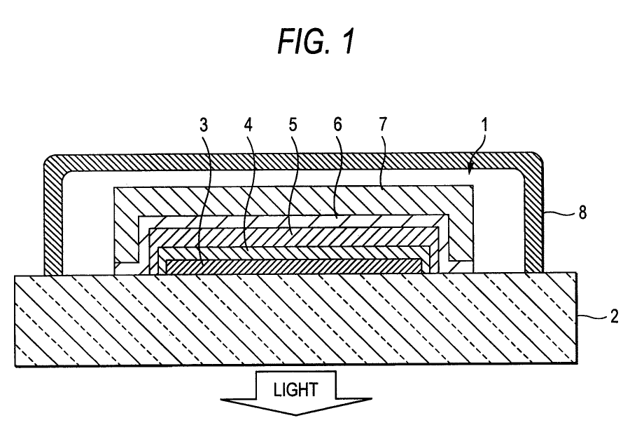

FIG. 1 is a sectional view showing a structure of an organic electroluminescent device according to an embodiment of the invention.

A numeral 1 stands for an organic electroluminescent device, which is configured to include a glass substrate 2 made of a translucent glass material; ITO (indium tin oxide) as an anode 3 formed on this glass substrate 2; a poly(ethylenedioxy)thiophene (PEDOT) as a hole injection layer 4 further formed on this upper layer; a light emitting layer 5 made of a polymer material; an electron injection layer 6 made of a metal oxide; and a cathode 7 made of a metal material.

When a direct current voltage or a direct current is impressed to the organic electroluminescent device 1 while making the anode 3 act as a plus electrode and also making the cathode 7 act as a minus electrode, not only a hole is injected into the light emitting layer 5 from the anode 3 via the hole injection layer 4, but an electron is injected into the light emitting layer 5 from the cathode 7 via the electron injection layer 6. In the light emitting layer 5, when the thus injected hole and electron are recombined with each other, and an exciton formed following this moves from an excited state to a ground state, a luminous phenomenon takes place.

According to the organic electroluminescent device 1 of the present embodiment, a light emitting layer with a large area can be formed, an aspect of which is a characteristic feature of a polymer material; a uniform luminous characteristic can be obtained; and furthermore, the formation of a cathode, which is usually carried out by a vapor deposition method, can be achieved without adopting a high-vacuum process. Therefore, the manufacturing process can be made simple. At that time, when a commercially available transparent electrode is used, it is possible to constitute a manufacturing process which does not require a high-vacuum process.

Next, the manufacturing steps of the organic electroluminescent device 1 of the invention are described.

First of all, an ITO film having a thickness of 150 nm was formed on the no-alkali glass substrate 2 to be used as a supporting substrate by a sputtering method; and thereafter, a resist material was coated on the ITO film by a spin coating method, thereby forming a resist film having a thickness of 10 μm, which was then subjected to mask exposure and developed, thereby pattern forming the resist film in a prescribed shape.

Subsequently, this glass substrate 20 was dipped in 50% hydrochloric acid at 60° C., thereby etching the ITO film in a portion where the resist film was not formed, and thereafter, the resist film was also removed. There is thus formed the anode 3.

Subsequently, the hole injection layer 4 is formed. PEDOT was dropped through a filter of 0.45 μm and uniformly coated on the substrate surface by a spin coating method. This was heated in a clean oven at 200° C. for 30 minutes. There is thus formed the hole injection layer 4.

Subsequently, a xylene solution having a light emitting material made of a polymer dissolved therein was coated by means of spin coating and then heat treated, thereby forming the light emitting layer 5 having a prescribed film thickness.

Subsequently, separately from the laminate composed of the anode 3, the hole injection layer 4 and the light emitting layer 5 on the glass substrate 2, a metal oxide layer made of, for example, zinc oxide is previously formed as the electron injection layer 6 on the surface of a cathode material which is a material in a solid plate form.

Finally, by using the cathode material in a solid plate form having the electron injection layer 6, disposing the cathode material on the organic layer and then heat softening it to join the cathode 7 with the organic layer, the organic electroluminescent device 1 of the invention is formed.

A metal material having a small electrical resistivity, which is capable of being softened at a low temperature, is suitable for the electrode material in a solid plate form, and the softening and formation by heating at a lower temperature leads to a reduction of the damage to the organic material.

At that time, in disposing the cathode material, by using an auxiliary substrate not shown in FIG. 1 and disposing the cathode material on this auxiliary substrate by patterning, it is possible to dispose the cathode material at a high positional precision with the anode 3 without causing a scar at the time of contact.

After the disposition, the resultant was inserted into a fixing tool and fixed by a clamp such that a shear was not caused. Also, in heat softening the cathode material at a prescribed temperature, by applying a load to the foregoing auxiliary substrate, favorable junction with the light emitting layer 5 is obtainable regardless of recesses and projections.

Though this auxiliary substrate may be removed after the formation of the cathode 7, it may be allowed to stand as it is disposed. Furthermore, by forming a sealing part 8, the reliability of the organic electroluminescent device 1 can be enhanced. In the sealing part 8, though a surrounding area of the auxiliary substrate may be stuck to the glass substrate 2 by an adhesive or the like, by bonding a case cut into a bathtub shape with an adhesive and disposing a desiccant in a space within the adhesive or case, the reliability can be more enhanced.

### Example 1

The structure of the organic electroluminescent device is hereunder described in detail with reference to FIG. 1.

### (1) Substrate:

As the glass substrate 2 of FIG. 1, any material is useful so far as it has a mechanical or thermal strength and has a strength capable of holding an organic electroluminescent device. In the case where it is used as a surface from which light emission from the organic layer is extracted, any transparent or translucent material is useful so far as it has a function to effectively transmit light therethrough.

Also, though it is preferable that the glass substrate 2 is insulating, but there are no particular limitations. The glass substrate 2 may have conductivity within the range where the action of the organic electroluminescent device 1 is not hindered, or depending upon applications.

The glass substrate 2 is a colorless and transparent substrate as a first substrate. Examples of the glass substrate 2 which can be used include transparent or translucent inorganic oxide glasses such as a soda lime glass, a barium/strontium-containing glass, a lead glass, an aluminosilicate glass, a barium borosilicate glass or a quartz glass; and transparent or translucent inorganic glasses such as an inorganic fluoride glass.

Other materials can also be employed as the glass substrate 2. Examples thereof include polymer films using a transparent or translucent polymer material such as polyethylene terephthalate, polycarbonate, polymethyl methacrylate, polyethersulfone, polyvinyl fluoride, polypropylene, polyethylene, polyacrylate, amorphous polyolefins, fluorine based resins, polysiloxanes or polysilanes; and transparent or translucent materials such as chalcogenide glasses, for example, As₂S₃, As₄₀S₁₀, S₄₀Ge₁₀, etc., or metal oxides or nitrides, for example, ZnO, Nb₂O, Ta₂O₅, SiO, Si₃N₄, HfO₂, TiO₂, etc. Alternatively, in the case of extracting light to be outputted from the light emitting region without going through the substrate, an opaque semiconductor material such as silicon, germanium, silicon carbide, gallium arsenic or gallium nitride, the foregoing transparent substrate material containing a pigment or the like and a metal material whose surface has been subjected to an insulating treatment can be properly chosen and used. A laminated substrate obtained by laminating plural substrate materials can also be used. Also, a material capable of transmitting only light of a specified wavelength therethrough, a material having a light-light conversion function, which is capable of converting light into light having a specified wavelength, and the like may be used.

### (2) Anode:

On the glass substrate 2 chosen among the foregoing materials, a transparent conductive film made of a metal oxide such as indium tin oxide (ITO), tin oxide (SnO₂) or zinc oxide (ZnO) or a mixture such as SnO/Sb (antimony), ZnO/Al (aluminum) or IZO (In₂O₃/ZnO); a metal thin film having a thickness to an extent that the transparency is not impaired, which is made of, for example, Al (aluminum), Cu (copper), Ti (titanium) or Ag (silver); a metal thin film such as a mixed thin film or a laminated thin film made of such metals; a conductive polymer such as polypyrrole; or the like can be used as the transparent anode 3.

Also, ITO of a coating type to be baked after coating and forming a coating film composed mainly of an indium compound having a relatively high resistance; a conductive polymer compound such as polythiophene (poly(ethylenedioxy)thiophene, hereinafter referred to as “PEDOT”), polyphenylenevinylene (hereinafter referred to as “PPV”) and a polyolefin; and the like can also be used. In order to bring sufficient transparency, it is desirable to make the anode 3 have a thickness of not more than 500 nm. In general, in view of the fact that a small resistance value is desirable, an anode made of a transparent conductive film such as ITO formed by a sputtering method, a resistance heating vapor deposition method or the like is useful.

### (3) Hole Injection Layer:

As the hole injection layer 4 of FIG. 1, one having a high hole mobility and good deposition properties is preferable. Examples thereof include organic materials such as porphyrin compounds, for example, N,N′-diphenyl-N,N′-bis(3-methylphenyl)-1,1′-diphenyl-4,4′-diamine, porphine, tetraphenylporphine copper, phthalocyanine, copper phthalocyanine, titanium phthalocyanine oxide, etc.; aromatic tertiary amines, for example, 1,1-bis{4-(di-p-tolylamino)phenyl}cyclohexane, 4,4′,4″-trimethyltriphenylamine, N,N,N′,N′-tetrakis(p-tolyl)-p-phenylenediamine, 1-(N,N-di-p-tolylamino)naphthalene, 4,4′-bis(dimethylamino)-2,2′-dimethyltriphenylmethane, N,N,N′,N′-tetraphenyl-4,4′-diaminobiphenyl, N,N′-diphenyl-N,N′-di-m-tolyl-4,4′-diaminobiphenyl, N-phenylcarbazole, etc.; stilbene compounds, for example, 4-di-p-tolylaminostilbene, 4-(di-p-tolylamino)-4′-[4-(di-p-tolylamino)styryl]stilbene, etc.; triazole derivatives; oxadiazole derivatives; imidazole derivatives; polyarylalkane derivatives; pyrazoline derivatives; pyrazolone derivatives; phenylenediamine derivatives; anilamine derivatives; amino-substituted chalcone derivatives; oxazole derivatives; styrylanthracene derivatives; fluorenone derivatives; hydrazone derivatives; silazane derivatives; polysilane based aniline based copolymers; polymer oligomers; styrylamine compounds; aromatic dimethylidyne based compounds; or polythiophene derivatives, for example, poly-3,4-ethylenedioxythiophene (PEDOT), tetradihexylfluorenyl biphenyl (TFB), poly-3-methylthiophene (PMeT), etc.

Also, a hole transport layer of a polymer dispersion system obtained by dispersing a low molecular weight organic material for hole transport layer in a polymer such as polycarbonate is useful.

Also, an inorganic oxide such as MoO₃, V₂O₅, WO₃, TiO₂, SiO or MgO may be used. As the deposition method, a wet process such as a spin coating method, a slit coating method or an inkjet method, or a dry process such as a vacuum vapor deposition method can be adopted.

### (4) Light Emitting Layer:

In Example 1, as to the light emitting layer 5, by using a polymer organic electroluminescent material as described later and adopting a spin coating method which is one of wet processes in which the step is simple, and a reduction of the cost can be achieved, the light emitting layer 5 is formed by coating.

In general, the polymer organic electroluminescent material refers to an organic electroluminescent material which is deposited by a wet process such as a spin coating method; and the low molecular weight organic electroluminescent material refers to an organic electroluminescent material which is deposited by a dry process such as a vacuum vapor deposition method. Strictly speaking, an organic electroluminescent material to which a dry process such as a vacuum vapor deposition method cannot be applied is referred to as the polymer organic electroluminescent material.

The reason why a vacuum vapor deposition method cannot be applied to the polymer organic electroluminescent material resides in the fact that in the polymer organic electroluminescent material, self molecular motion occurs before vaporization, and the main chain is cut.

That is, this causes reduction of the molecular weight, whereby an inherent capability of the material is lowered.

In coating and forming the light emitting layer 5 made of a polymer material by a spin coating method, in Example 1, MEH-PPV dissolved in toluene is used as the polymer organic electroluminescent material, and the film thickness is set to be 120 nm. The MEH-PPV is common as the polymer organic electroluminescent material and is, for example, commercially available from Nihon SiberHegner K. K. Other than this, styrene based conjugated dendrimers and the like can be used as the polymer organic electroluminescent material.

In the case where the light emitting layer 5 is coated by the foregoing spin coating method, the polymer organic electroluminescent material is coated on all the structures formed on the glass substrate 2 prior to the formation of the light emitting layer 5. The polymer organic electroluminescent material is large in permeability of moisture, etc., and when it exists in an unnecessary portion, it becomes a penetration passage of moisture, etc. and becomes a large cause of deterioration of the organic electroluminescent device 1. Therefore, in such case, it is desirable that prior to the formation of the cathode 7 as described later, for example, a solvent such as toluene or xylene is recoated, and only a prescribed region is wiped off with manufacturing equipment for recovery thereof together with the molten polymer organic electroluminescent material. The wiping-off step can also be carried out by, for example, a laser ablation method.

Also, in the case where a polymer organic electroluminescent material is coated in only a prescribed region as in a flat printing method using an inkjet technology, the foregoing wiping-off step becomes unnecessary.

After this wiping-off step, the light emitting device substrate is allowed to stand under an environment at about 130° C. for about one hour, thereby sufficiently evaporating off the organic solvent (for example, toluene or xylene) which is a solvent in which the polymer organic electroluminescent material is dissolved (baking step). The temperature in the baking step is hereinafter referred to as “baking temperature”.

Next, characteristics of the polymer organic electroluminescent material are described in details by comparison with a conventional low molecular weight organic electroluminescent material.

Among the light emitting materials constituting the organic electroluminescent device 1, low molecular weight organic electroluminescent materials which have hitherto been frequently used are generally formed in an amorphous thin film by deposition of the organic compound group by means of vacuum vapor deposition. Therefore, it is known that they are weak to a high-temperature environment, and the heat resistance temperature is assumed to be one hundred and several tens ° C. at most.

This is because when exposed to a high-temperature environment, crystallization of the low molecular weight organic compound is advanced, whereby characteristics as the light emitting material are deteriorated.

On the other hand, in the polymer organic electroluminescent material, a thin film is constituted by complicated entanglement of long molecule chains. Thus, a distinct crystallization temperature does not exist, and only an index which should be referred to as a softening starting temperature which is a glass transition point is present.

Furthermore, in a large number of polymer organic electroluminescent materials, there may be the case where even a distinct glass transition point is not observed.

In other words, in polymer organic electroluminescent materials, in view of the constitution in which molecules are entangled, they cannot move freely to achieve crystallization.

Such a characteristic feature of the polymer organic electroluminescent material appears as great superiority of high heat resistance when the polymer organic electroluminescent material is applied to the organic electroluminescence device 1. This heat resistance temperature including that of HEM-PPV as already described sufficiently exceeds 200° C.

The light emitting layer 5 constituted of the polymer organic electroluminescent material having such a significant characteristic feature of high heat resistance is not deteriorated in light emission characteristics even by a heat stress applied in the manufacturing steps, thereby making it easy to design a manufacturing process.

However, even in low molecular weight organic electroluminescent materials which are deposited by adopting a dry process such as a vacuum deposition method, oligomers having a large molecular weight and a relatively high glass transition point, more specifically, a PPV oligomer or the like, have exceptionally high heat resistance, and a wet process can be easily applied thereto. Therefore, they can be used for the light emitting material of the invention as a substitute for the polymer organic electroluminescent material.

In Example 1, the light emitting layer 5 was formed in a single layer film made of MEH-PPV. However, it may also be a laminated film made of some materials. For example, in order to confine a charge injected into the MEH-PPV layer to enhance the recombination efficiency, what a layer made of a material having an electron blocking function or a hole blocking function is added is desirable because this leads to an enhancement of the characteristics of the device.

Specifically, the light emitting layer 5 may be configured to include a three-layer structure of hole transport layer/electron blocking layer/the foregoing organic light emitting material (all not shown) in this order from the side of the anode 3, or the light emitting layer 5 may be configured to include a two-layer structure of electron transport layer/organic light emitting material (both not shown) in this order from the side of the cathode 7. Alternatively, the light emitting layer 5 may also be configured to include a two-layer structure of hole transport layer/organic light emitting material (both not shown) in this order from the side of the anode 3, or it may be configured to include a five-layer structure of hole transport layer/electron blocking layer/organic light emitting layer/hole blocking layer/electron transport layer (all not shown) in this order from the side of the anode 3.

Thus, the case where a layer is referred to as the light emitting layer 5 in Example 1 also includes the case where the light emitting layer 5 has a multilayered structure having functional layers such as a hole transport layer, an electron blocking layer or an electron transport layer.

Also, as the hole transport layer which is included in the light emitting layer 5, one which has a high hole mobility, is transparent and has good deposition properties is preferable. Besides TPD described in the Background Art, there are used organic materials such as porphyrin compounds, for example, porphine, tetraphenylporphine copper, phthalocyanine, copper phthalocyanine, titanium phthalocyanine oxide, etc.; aromatic tertiary amines, for example, 1,1-bis{4-(di-p-tolylamino)phenyl}cyclohexane, 4,4′,4″-trimethyltriphenylamine, N,N,N′,N′-tetrakis(p-tolyl)-p-phenylenediamine, 1-(N,N-di-p-tolylamino)naphthalene, 4,4′-bis(dimethylamino)-2,2′-dimethyltriphenylmethane, N,N,N′,N′-tetraphenyl-4,4′-diaminobiphenyl, N,N′-diphenyl-N,N′-di-m-tolyl-4,4′-diaminobiphenyl, N-phenylcarbazole, etc.; stilbene compounds, for example, 4-di-p-tolylaminostilbene, 4-(di-p-tolylamino)-4′-[4-(di-p-tolylamino)styryl]stilbene, etc.; triazole derivatives; oxadiazole derivatives; imidazole derivatives; polyarylalkane derivatives; pyrazoline derivatives; pyrazolone derivatives; phenylenediamine derivatives; anilamine derivatives; amino-substituted chalcone derivatives; oxazole derivatives; styrylanthracene derivatives; fluorenone derivatives; hydrazone derivatives; silazane derivatives; polysilane based aniline based copolymers; polymer oligomers; styrylamine compounds; aromatic dimethylidyne based compounds; or polythiophene derivatives, for example, poly-3,4-ethylenedioxythiophene (PEDOT), tetradihexylfluorenyl biphenyl (TFB), poly-3-methylthiophene (PMeT), etc.

Also, a hole transport layer of a polymer dispersion system obtained by dispersing a low molecular weight organic material for hole transport layer in a polymer such as polycarbonate is useful.

Also, such a hole transport material can be used as an electron blocking material.

Furthermore, as the electron transport layer in the foregoing light emitting layer 5, there is used a polymer material composed of an oxadiazole derivative such as 1,3-bis(4-tert-butylphenyl-1,3,4-oxadiazolyl)phenylene (OXD-7), an anthraquinodimethane derivative, a diphenylquinone derivative or a silole derivative, or bis(2-methyl-8-quinolinolate)-(para-phenylphenolate) Al(BAlq), bathocuproine (BCP) or the like.

Also, such a material capable of constituting the electron transport layer can be used as a hole blocking material.

In the light of above, the light emitting layer 5 in Example 1 has been described in detail, but it should not be construed that the polymer organic electroluminescent material forming the light emitting layer 5 is limited to the foregoing MEH-PPV. One having a fluorescent or phosphorescent characteristic in a visible region and good deposition properties can be chosen. For example, a polymer light emitting material such as polyparaphenylene vinylene (PPV) or polyfluorene, or the like can be used.

Furthermore, polymer based organic electroluminescent materials having various characteristics and light emission colors are proposed at present. The light emitting layer 5 can be constituted by properly choosing a material among these materials.

### (5) Electron Injection Layer:

The electron injection layer 6 of FIG. 1 is made of a metal oxide including zinc oxide (ZnO) and titanium oxide (TiO₂) each having a function to inject an electron into the organic layer, and in Example 1, zinc oxide was used for the electron injection layer.

Also, in Example 1, a sputtering method was adopted as the deposition method of the electron injection layer. Besides, a dry process such as a resistance heating vapor deposition method, an EB vapor deposition method, an MOD method or a CVD method; a wt process such as an electro-deposition method using a plating technology, a sol-gel method, an LB method, a spin coating method, a slit coating method or an inkjet method; and the like can be adopted.

The surface of the counter electrode in a solid plate form is cleaned by a UV ozone treatment, and the counter electrode is then fixed to a substrate holder such that the cleaned surface thereof is exposed. The substrate holder having the counter electrode fixed thereto is introduced into a sputtering apparatus (SPF332, manufactured by Anelva Corporation), and a layer of zinc oxide was formed on the counter electrode by means of RF sputtering. As a target which was used at that time, a zinc oxide target of Kojundo Chemical Laboratory Co., Ltd. was used. Though argon was used as a gas to be introduced, a mixed gas having a small amount of oxygen added thereto may be used. The deposition was carried out at a deposition rate of 1 angstrom/sec. The deposition must be carried out such that the temperature in the vicinity of the counter electrode at the time of deposition does not exceed a liquid phase temperature of the counter electrode material.

Also, in not only the sputtering method but other dry process or wet process, in the case of applying a heat treatment in the step of depositing the electron injection layer on the counter electrode, the treatment temperature of the counter electrode should not exceed the liquid phase temperature of the counter electrode material.

By the foregoing step, the counter electrode having the electron injection layer in which the deposition has been completed is heat joined with the organic layer, thereby forming the organic electroluminescent device of the invention.

Next, the luminous efficiency of the actual organic electroluminescent device relative to the film thickness of zinc oxide which was the electron injection layer material in Example 1 of the invention is described.

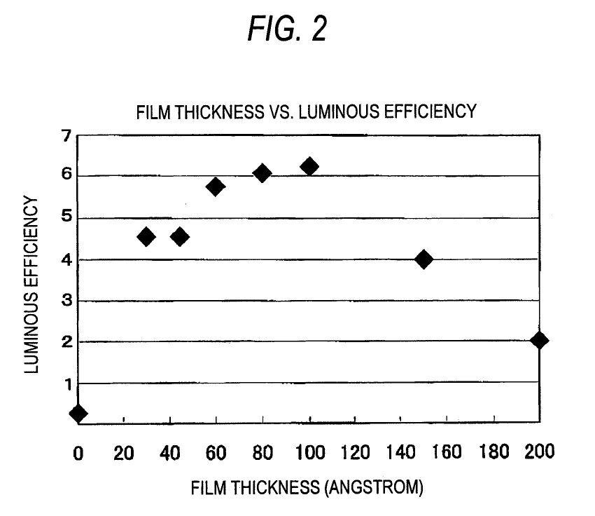

FIG. 2 is an explanatory view of dependency of luminous efficiency of the organic electroluminescent device according to Example 1 of the invention upon a film thickness of an electron injection layer.

From the results of FIG. 2, an enhancement of the luminous efficiency could be conformed within the range of from 10 angstroms to 200 angstroms in terms of a film thickness of the electron injection layer, and the organic electroluminescent device 1 with more enhanced luminous efficiency was obtained within the range of from 60 angstroms to 100 angstroms.

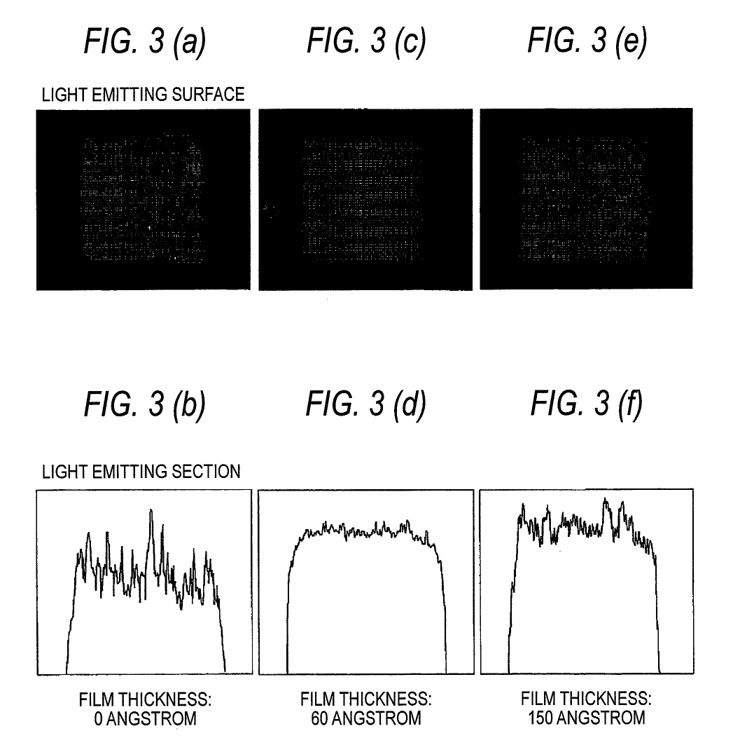

FIG. 3 is a view showing a light emitting surface and a light emitting section of the organic electroluminescent device according to Example 1 of the invention. In FIG. 3, photographs (FIGS. 3A, 3C and 3E) of the light emitting surface and light emitting sectional views (FIGS. 3B, 3D and 3F) at the time of light emission of the light emitting part of the organic electroluminescent device in Example 1 are shown.

The photograph of the light emitting surface shown in FIG. 3A and the light emitting sectional view shown in FIG. 3B are concerned with a device which is not provided with an electron injection layer in the organic electroluminescent device 1 of the invention, namely, a device in which the film thickness of the electron injection layer in the organic electroluminescent device 1 of the invention is 0 angstrom. Though the results of FIG. 2 reveal that the luminous efficiency is low, the light emitting surface is not uniform, the uniformity of the light emitting section is greatly disordered, and therefore, it is understood that the injection of an electron into the organic layer is not carried out efficiently and uniformly.

On the other hand, the photograph of the light emitting surface shown in FIG. 3C and the light emitting sectional view shown in FIG. 3D are concerned with a device in which the film thickness of the electron injection layer in the organic electroluminescent device 1 of the invention is 60 angstroms. The results of FIG. 2 reveal that the luminous efficiency is enhanced; it may be said that the uniformity of the light emitting surface and that the light emitting section is substantially uniform; and it is understood that the injection of an electron into the organic layer is carried out efficiently and uniformly.

Also, the photograph of the light emitting surface shown in FIG. 3E and the light emitting sectional view shown in FIG. 3F are concerned with a device in which the film thickness of the electron injection layer in the organic electroluminescent device 1 of the invention is 150 angstroms. The results of FIG. 2 reveal that the luminous efficiency is lowered; the uniformity of the light emitting surface or light emitting section is impaired; and it is understood that the injection of an electron into the organic layer is not carried out uniformly.

From the foregoing results, there were obtained results that the film thickness at which the most uniform light emitting surface is obtained is 60 angstroms, whereas when the film thickness is 150 angstroms, the uniformity of the light emitting surface is impaired.

### (6) Cathode:

In Example 1, the foregoing material having the foregoing electron injection layer deposited thereon is disposed on the organic layer and then softened to form the cathode 7. A metal material having a small electrical resistivity, which is capable of being softened at a low temperature, is suitable for the cathode material, and in Example 1, ECO SOLDER M716, manufactured by Senju Metal Industry Co., Ltd. was used.

It should not be construed that the electrode material is limited to the foregoing ECO SOLDER M716 used in Example 1. In forming the cathode 7 on the light emitting layer 5, the cathode 7 is formed in a shape necessary for a cathode. In Example 1, by using a 0.05 mm-thick plate material and using an auxiliary substrate not described in FIG. 2, the cathode material is subjected to patterning on the auxiliary substrate and disposed.

Since the cathode material is fixed to the auxiliary substrate, a registration marker is provided on both of the glass substrate 2 and the auxiliary substrate, and it becomes possible to dispose the cathode material at a high positional precision with the anode 3 without causing a scar at the time of contact by adjusting at a high precision by visual inspection or by using a CCD camera, etc. After the disposition, the resultant is inserted into a fixing tool and fixed by a clamp such that a shear is not caused.

Subsequently, the electrode material in a solid plate form is heated and softened to achieve junction with the light emitting layer 5. At that time, when the solid electrode material is rendered in a completely molten state, in the case where deformation of the electrode shape is caused due to the generation of aggregation, or a load is applied via the auxiliary substrate or the like, outflow occurs, whereby the formation of a cathode cannot be achieved. Therefore, the junction is carried out at a temperature of not higher than a melting temperature.

In Example 1, the junction was carried out at a peak temperature of 206° C. which is lower than 214° C. as a liquid phase temperature of the ECO SOLDER M716. In order to make the junction state good, the temperature which is set in the heat junction is desirably a softening temperature of the solid electrode or higher. However, at that time, it is also necessary to set the heating time for achieving the junction upon heating such that in order that outflow of the electrode material due to the molten state may not be caused, a heat capacity to be applied is smaller than a heat capacity at which the solid electrode is completely molten. In Example 1, the heating time was set to be 20 minutes.

Also, in heat softening the cathode material, by applying a load to the foregoing auxiliary substrate, favorable junction can be obtained regardless of recesses and projections of the light emitting layer 5. Though this auxiliary substrate may be removed after the formation of the cathode 7, it may be allowed to stand as it is disposed.

In Example 1, the same substrate as the glass substrate 2 was used. However, the auxiliary substrate is not necessarily transparent, and any material is useful so far as it is hardly deformed at the time of heating, for example, a heat-resistant resin, a metal, a metal oxide, a sintered material, etc.

Also, in Example 1, in heat joining the electrode in a solid plate form having the electron injection layer formed thereon with the organic layer, a heating furnace is used. At that time, by reducing a gas partial pressure of the environment within the heating furnace by using a rotary pump, it becomes possible to prevent the retention of air bubbles at an interface between the organic layer and the electrode at the time of joining the solid electrode, the injection of a charge into the organic layer becomes uniform due to the uniform junction at the interface between the organic layer and the electrode, and the uniformity of light emission is enhanced. Also, in view of the fact that the uniformity of junction is enhanced, it is possible to easily form an electrode with a large area.

Also, in the invention, in addition to the foregoing electrode material in a solid plate form, 50% or more of tin may be contained in the electrode material in a solid plate form.

According to this configuration, since the hardness of the electrode in a solid plate form is significantly lowered, not only forming of the electrode is easy, but the generation of a scar in the organic layer can be reduced.

Furthermore, any one or more kinds of silver, indium, bismuth, zinc, copper and aluminum may be contained. According to this configuration, the softening temperature of the electrode is reduced, and the hardness of the alloy is reduced.

Moreover, indium and zinc are high in the charge injection characteristic and enhance the injection efficiency. Also, it is preferable that silver and magnesium are contained. According to this configuration, because of an alloy of magnesium and silver, magnesium can be handled relatively stably, and the charge injection characteristic can be enhanced.

Also, the electrode in a solid plate form may be configured to include two layers of a layer made of a metal material having a heat deformation temperature of the electrode material of not higher than 250° C. and a layer made of a metal material having a low electrical resistance value.

For example, when the electrode in a solid plate form is configured to include a layer made of a low-temperature heat deforming metal material containing a large amount of tin, which is a low-melting point metal material and a layer made of silver, copper, gold, aluminum, etc., the electrical resistance value as an electrode can be made small, and therefore, it becomes possible to feed a uniform charge over a large area.

### (7) Sealing Part:

By forming the sealing part 8, the reliability of the organic electroluminescent device 1 can be enhanced. In the sealing part 8, though a surrounding area of the foregoing auxiliary substrate may be stuck to the glass substrate 2 by an adhesive or the like, by bonding a case cut into a bathtub shape with an adhesive and disposing a desiccant in a space within the adhesive or case, the reliability can be more enhanced. Also, sealing can be achieved by coating an insulating resin directly on the electrode and curing it.

According to this configuration, the cathode 7 is contact disposed in a fixed plate form on the organic material layer, and the cathode 7 is fixed in a solid shape; and therefore, not only handling is easy, but it is possible to perform forming only in a necessary portion, thereby making it easy to prepare an arbitrary complicated shape.

Also, by performing heat softening, junction with the organic layer formed on the anode 3 on the glass substrate or a structure having recesses and projections such as an insulating layer is excellent, and by applying an appropriate load, it is possible to enhance the junction precision.

Also, the cathode material is solid, and therefore, it is possible to previously control the film thickness of the cathode 7. Also, for the purpose of making the current density uniform, it is also possible to prepare the cathode 7 having a partially different film thickness, if desired. Also, it is possible to realize uniform light emission with a high luminance even in large areas as in, for example, a backlight, a light source or the like.

Also, the cathode material is not made in a completely molten state at the time of formation, and therefore, it is possible to prepare the extremely thick cathode 7 within a short period of time without generating aggregation due to an intermolecular force generated when the fluidity is high.

Furthermore, when the film thickness of the cathode 7 is thick, the covering effect relative to the organic layer is increased, and barrier properties relative to a material which is damaged by moisture, oxygen, etc. from the outside of the organic layer or the like are revealed. Also, by devising the covering shape, it is possible to impart an effect as the sealing layer 8.

Also, in view of the fact that the cathode material is solid, by partially changing the composition of the electrode material to provide a portion having a large charge mobility relative to the organic layer and high junction properties and a portion having high charge conductivity, it is possible to tremendously enhance the efficiency as an organic device. At that time, by increasing the surface area of the cathode 7 within the range where scattering of the electric field density is not generated, it is possible to enhance the efficiency of charge injection.

Also, by disposing the inorganic oxide layer between the organic layer and the cathode 7, it is easy to inject an electron into the organic layer, and it is possible to achieve an enhancement of the luminous efficiency of the organic electroluminescent device 1, a lowering of the driving voltage and a reduction of the consumed power. The organic electroluminescent device 1 is inert against oxygen, moisture, etc., and influences of reactive materials can be reduced, whereby it becomes possible to obtain a long-term electron injection characteristic; and it is possible to form the electron injection layer 6 without damaging the organic layer. As a result, it becomes possible to provide the organic electroluminescent device 1 with a long life.

Also, a carrier balance can be adjusted, and, for example, the light emission is realized on a center of the light emitting layer 5, whereby the breakage of the interface can be suppressed. Also, thermal deactivation of an exciton can be suppressed, and the organic electroluminescent device stably works and is excellent in a life characteristic.

### Example 2

In the foregoing Example 1, zinc oxide as the metal oxide was deposited by adopting a sputtering method as the deposition method of the electron injection layer. However, in Example 2, for the purpose of realizing a preparation process of an organic electroluminescent device which does not require a high-vacuum process requiring a large amount of plant and equipment investment, such as a vapor deposition method or a sputtering method and which is able to significantly minimize the plant and equipment investment, the deposition of an electron injection layer made of a metal oxide was carried out by adopting a plating method which is a wet process for a method of depositing the electron injection layer.

According to Example 2, the electron injection layer deposited on the cathode 7 which is a counter electrode is an extremely thin film, and therefore, zinc deposited on the cathode 7 is oxidized in a bath or the atmosphere immediately after the plating treatment.

According to this, a desired metal oxide is obtainable without performing a special oxidization treatment, and therefore, handling is very easy. Different from films made of an alkali metal, an alkaline earth metal or an oxide or fluoride thereof, which are generally used as an electron injection material of an organic electroluminescent device, the deposition treatment can be carried out in a usual environment or a usual atmosphere.

Also, in the case of comparing an organic electroluminescent device using titanium oxide which is similarly a metal oxide for the electron injection layer, an organic electroluminescent device with high luminous efficiency was obtained. Furthermore, the formation by a plating method is difficult for the deposition of titanium or titanium oxide, and therefore, the deposition of zinc oxide as an electron injection layer was carried out by a zinc electroplating method.

In Example 2, the deposition step of the electron injection layer 6 described in Example 1 was carried out by a plating method in place of the sputtering method which is a high-vacuum process. The configuration of the organic electroluminescent device of the invention (FIG. 1) and other members and methods are identical with the materials and manufacturing steps in, for example, the substrate 2, the anode 3, the hole injection layer 4, the light emitting layer 5, the cathode 7 and the sealing part 8. In consequence, Example 2 is described with reference to FIG. 1.

The surface of the cathode 7 in a solid plate form is subjected to a degreasing treatment upon being dipped in acetone. Though a neutral or alkaline detergent may be used for the degreasing treatment, degreasing and cleaning with a solvent which retains a little on the cathode material were carried out in Example 2.

Though a degreasing step and a drying step after cleaning are necessary for the solvent, acetone was used as the solvent in Example 2. Cleaning was carried out by dipping the above-formed cathode 7 in acetone on a reagent level and subjecting it to fluctuation. At that time, by impressing ultrasonic waves, a cleaning effect can be enhanced, and therefore, the cleanliness of the surface is low. Thus, in the case where the amount of deposits is large, the impressing of ultrasonic waves is properly carried out.

Also, by using the foregoing solvent, drying can be rapidly performed after cleaning without carrying out a drying step by steam cleaning. In the drying step using acetone, in order that a stain due to dew condensation of moisture in an atmosphere may not be generated by rapidly removing the solvent, liquid removing and drying with a compressed air of at least −40° C. lower than the dew point were carried out.

Subsequently, after cleaning by a UV ozone treatment, the cathode 7 is fixed to a substrate holder having a mask opened so as to make the plated surface have a fixed area in such a manner that the cleaned surface thereof is exposed.

At that time, it is desirable that the area of the cathode 7 opened by the mask falls within the range of from 1.0 to 1.6 times the area of the non-plated electrode. According to this, it is possible to enhance the uniformity of the electric field distribution. On the contrary, when the area of the cathode 7 opened by the mask is equal to or less or excessively large relative to the area of the non-plated electrode, the electric field concentration into the end occurs, whereby a non-uniform plated film is formed.

In Example 2, in order to deposit a zinc-plated film on the cathode 7, DIPSOL NZ-98, manufactured by Dipsol Chemicals Co., Ltd. was used. However, it should not be construed that the plating material for forming the electron injection layer 6 described in Example 2 is limited to the foregoing DIPSOL NZ-98.

The substrate holder having the cathode 7 fixed thereto is fixed in parallel using a fixing tool such that it is disposed at equal distances to an electroplating control electrode (non-plated electrode), and the both electrodes to which a voltage is impressed are connected to each other. This is dipped in a plating bath and placed. The plating bath is adjusted so as to have a zinc concentration of 12 g/liter and a sodium hydroxide concentration of 140 g/liter, thereby achieving initial make-up of electrolytic bath; 10 mL/liter of a brightener NZ-98S and 20 mL/liter of a conditioner NZ CONDITIONER are added thereto; the thus prepared plating bath is then adjusted at a liquid temperature of 25° C.; and the plating treatment is carried out while stirring the solution by a stirrer rotating at 60 rpm. As to the plating treatment condition, a constant-current power source is used, and an anode current density is set to be 4 A/dm². The film thickness can be controlled by turning on electricity with 1 A/dm² such that the measured efficiency relative to a factor of the deposited thickness of 0.285 μm/min is 0.6 times. After the plating treatment, cleaning with deionized water and degreasing drying with the foregoing acetone were rapidly carried out.

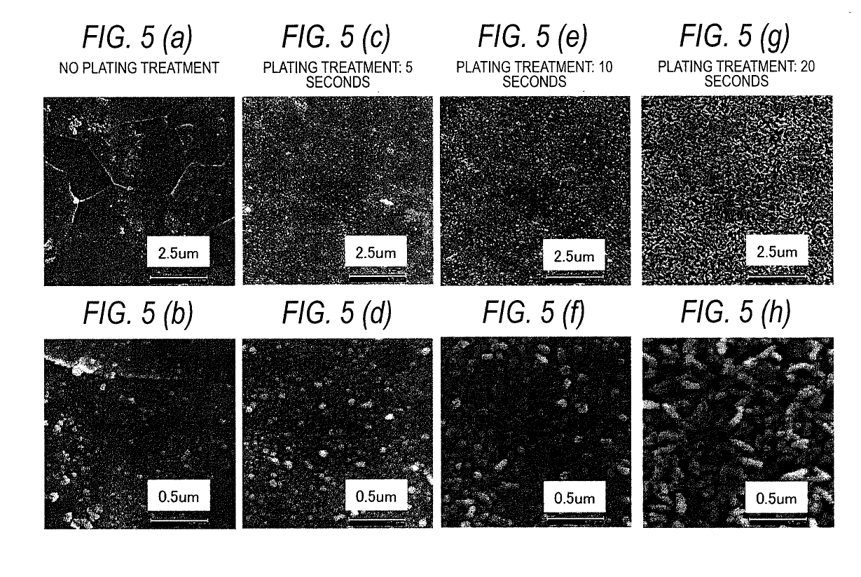

The treatment time was set to be 5 seconds, 10 seconds and 20 seconds, respectively, and the respective results are shown in FIGS. 5A to 5H. FIGS. 5A to 5H are described later in detail. At that time, the impressing of a current may be dividedly carried out twice, or after impressing a current in the forward direction, the impressing of a current may be carried out dividedly from that in the reverse direction.

Though the plating treatment by impressing of a current relies upon a desired thickness of the plated film, different from general plated films, the plated film in the invention is extremely thin. Therefore, in order to enhance the uniformity of the plated film, it is preferable to carry out the plating treatment dividedly twice or more. That is, though the control of the film thickness of zinc electroplating is in proportion to an electrochemical equivalent, it is difficult to make the electric field distribution into a subject of plating completely uniform. Moreover, the composition of the plating bath varies with deposition of zinc, and therefore, strictly speaking, the plating condition is changed as compared with that at the initial stage. For that reason, by dividing the zinc electroplating treatment, it is possible to precisely control the film thickness.

Also, the film thickness of zinc electroplating in the invention is not more than several tens nm, the film thickness is extremely small as compared with that in general plated films, and more precise control of the film thickness is necessary. However, by dividing the zinc electroplating treatment, more precise control of the film thickness becomes possible, whereby the electron injection layer of the invention is obtained. As a result, it becomes possible to realize an organic electroluminescent device with high efficiency.

Also, after impressing a current in the forward direction, by dividing the impressing of a current from that in the reverse direction, uniform plating becomes possible. Though the control of the film thickness of zinc electroplating is in proportion to an electrochemical equivalent, it is difficult to make the electric field distribution into a subject of plating completely uniform. Moreover, the composition of the plating bath varies with deposition of zinc, and therefore, strictly speaking, the plating condition is changed as compared with that at the initial stage. For that reason, by dividing the zinc electroplating treatment, it is possible to precisely control the film thickness.

Furthermore, when a reverse voltage is impressed for the purpose of relieving the concentration of an electric field, redissolution of a plated part deposited by a forward voltage occurs. As to the redissolution, the thicker the deposited portion, the more frequently the elution occurs. Thus, by properly carrying out the plating treatment by a reverse voltage, it consequently becomes possible to form a uniform zinc-electroplated film. As a yardstick of the plating treatment of the invention, it is desirable to carry out the plating treatment such that a ratio of the reverse plating to the forward plating is 1/2.

For a cyanide bath, MELZINC 2400, manufactured by Meltex Inc., which was adjusted so as to have a concentration of zinc oxide of 25 g/liter, a concentration of sodium cyanide of 40 g/liter and a concentration of sodium hydroxide of 80 g/liter, and a bath temperature of 25° C. and an anode current density of 5 A/dm² were employed as a standard condition.

An acid bath includes a zinc chloride plating bath, and above all, an ammonium chloride bath is desirable in Example 2 because it is excellent in brilliance. ACID ZINC 6420, manufactured by Nippon Hyomen Kagaku Kabushiki Kaisha, which was adjusted so as to have a concentration of zinc chloride of 40 g/litter and a concentration of ammonium chloride of 200 g/liter, and a bath temperature of 25° C., a pH of from 5.0 to 6.3 and an anode current density of 4 A/dm² were employed as a standard condition.

For a zincate bath, zinc oxide is dissolved in a sodium hydroxide solution so as to have a composition of 10 g/liter of zinc and 120 g/liter of sodium hydroxide, thereby achieving initial make-up of electrolytic bath, and the plating is carried out under a bath condition at a bath temperature of 20° C. and a pH of less than 14. Also, prior to the treatment, in order to remove deposits formed in the bath, the treatment is carried out while continuously achieving filtering using a cellulose- or Teflon-made filter with a filtration precision of not more than 5 μm. Also, the deposition and formation with a zinc electroless plating bath can be performed depending upon the shape and surface resistance value of the counter electrode to be subjected to a plating treatment.

According to the foregoing steps, the cathode 7 including the electron injection layer 6 having been completed for deposition is heat joined with the organic layer. There is thus formed the organic electroluminescent device 1 of the invention.

Next, the luminous efficiency of the organic electroluminescent device 1 relative to the deposition method of zinc oxide which is a material of the electron injection layer 6 in the Examples of the invention is described.

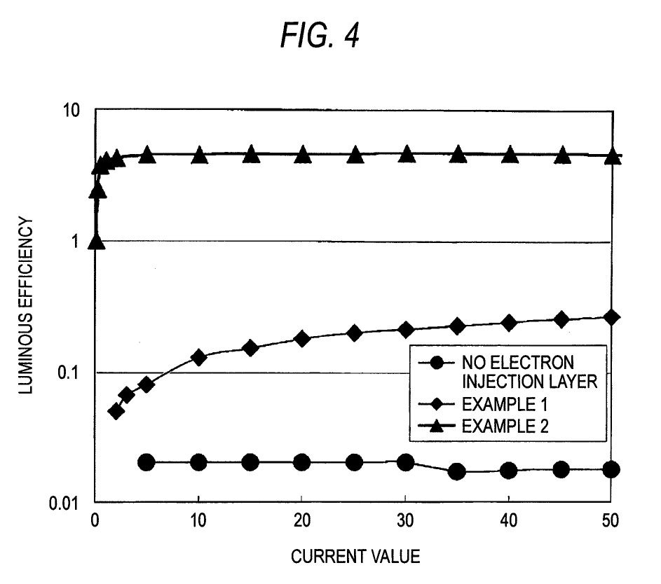

FIG. 4 is a graph showing the luminous efficiency of the electron injection layer 6 of the organic electroluminescent device 1 according to the Examples of the invention in a deposition method.

The luminous efficiency of the organic electroluminescent device 1 which is not provided with the electron injection layer 6 made of a metal oxide, namely, an organic electroluminescent device prepared by contact disposing only the cathode 7 in a solid plate form in the invention and heat and pressure forming it is shown with “” in FIG. 4.

Next, the luminous efficiency of the organic electroluminescent device 1 in which the electron injection layer 6 made of a metal oxide is formed by the sputtering method of Example 1, namely, the electroluminescent device 1 prepared by contact disposing the cathode 7 having the electron injection layer 6 formed thereon, which is prepared by forming zinc oxide on the cathode 7 in a solid plate form in the invention by a sputtering method, on the organic layer and heat and pressure forming it (the organic electroluminescent device 1 of Example 1) is shown with “♦” in FIG. 4.

Next, the luminous efficiency of the organic electroluminescent device 1 in which the electron injection layer 6 made of a metal oxide is formed by the plating method, namely, the organic electroluminescent device 1 prepared by contact disposing the cathode 7 having the electron injection layer 6 formed thereon, which is prepared by treating the cathode 7 in a solid plate form in the invention by a zinc electroplating method, on the organic layer and heat and pressure forming it (the organic electroluminescent device 1 of Example 2) is shown with “▴” in FIG. 4.

From the results shown in FIG. 4, it was confirmed that in the organic electroluminescent device 1 of Example 1 in which zinc oxide as the electron injection layer 6 is formed by a sputtering method, the luminous efficiency was enhanced by a factor of ten or more as compared with that in the organic electroluminescent device 1 not provided with the electron injection layer 6.

Furthermore, it was confirmed that in the organic electroluminescent device 1 of Example 2 in which zinc oxide as the electron injection layer 6 was formed by a zinc electroplating method, the luminous efficiency was enhanced by a factor of ten or more as compared with that in the organic electroluminescent device 1 of Example 1 in which the electron injection layer 6 was formed by a sputtering method.

For example, it may be considered that in the case of forming each of a sputtered film and a plated film so as to have the same film thickness, when the sputtered film is seen in a local point of view, namely as a particle constituting the film but not as a film, the in-plane uniformity of the deposited film is relatively high.

Also, a sputtering apparatus itself is an apparatus for forming a uniform film, and the sputtering apparatus is developed as one for forming a uniform film with respect to a design thought thereof.

On the other hand, in a process of forming an electroplated film, a deposit serving as a seed is formed on the electrode surface to be first deposited. Thereafter, a plated material is deposited while making the seed act as a nucleus. Therefore, from a local point of view, the uniformity of the film itself is low as compared with that of the sputtered film, and it may be considered that the film is a porous film. That is, when bonded to the organic layer, in view of the fact that the contact area becomes large, the contact surface where an electron can be injected into the organic layer becomes large. From this fact, it may be considered that a probability of enabling an electron to inject into the organic layer increases, whereby the luminous efficiency is enhanced.

Also, the sputtered film prepared by using, as a target, zinc oxide which is a metal oxide and the plated film made of zinc oxide prepared by depositing metallic zinc by a plating method in a bath and naturally oxidizing it are different from each other in a work function and a band gap due to a difference of the oxidation number, and it may be considered that the electron injection layer formed by the zinc electroplating method is higher in the electron injection characteristic.

Each of FIGS. 5A to 5H shows an electron microscopic photograph of the surface of the cathode 7 in a solid plate form having been subjected to a zinc electroplating treatment according to Example 2 of the invention.

FIG. 5A is an electron microscopic photograph of the surface of a cathode not subjected to a plating treatment, which is enlarged by a factor of 10,000; FIG. 5B is an electron microscopic photograph of the surface of FIG. 5A further enlarged by a factor of 5; FIG. 5C is an electron microscopic photograph of the surface of a cathode having been subjected to a zinc electroplating treatment for 5 seconds, which is enlarged by a factor of 10,000; FIG. 5D is an electron microscopic photograph of the surface of FIG. 5C further enlarged by a factor of 5; FIG. 5E is an electron microscopic photograph of the surface of a cathode having been subjected to a zinc electroplating treatment for 10 seconds, which is enlarged by a factor of 10,000; FIG. 5F is an electron microscopic photograph of the surface of FIG. 5E further enlarged by a factor of 5; FIG. 5G is an electron microscopic photograph of the surface of a cathode having been subjected to a zinc electroplating treatment for 20 seconds, which is enlarged by a factor of 10,000; and FIG. 5H is an electron microscopic photograph of the surface of FIG. 5G further enlarged by a factor of 5.

In the organic electroluminescent device formed from a cathode having a surface structure of a cathode not subjected to a plating treatment, as shown by the electron microscopic photographs of FIGS. 5A and 5B, and having a smooth surface state free from recesses and projections, the luminous efficiency was low.

It was confirmed that in the organic electroluminescent device formed from a cathode having a surface structure of a cathode having an electron injection layer, which was obtained by depositing a zinc-electroplated film thereon by a plating treatment for 5 seconds, as shown by the microscopic photographs of FIGS. 5C and 5B, and having a surface state where granular deposits were scatteredly deposited on the cathode surface by a zinc electroplating treatment, the luminous efficiency was significantly enhanced.

In the organic electroluminescent device formed from a cathode having a surface structure of a cathode having an electron injection layer, which was obtained by depositing a zinc-electroplated film thereon by a plating treatment for 10 seconds, as shown by the microscopic photographs of FIGS. 5E and 5F, and having a surface state where a deposit having a larger particle size than that of the granular deposits shown in FIG. 5D was deposited on the cathode surface more minutely than that shown in FIG. 5D by a zinc electroplating treatment, though the light emission was confirmed, the bond strength was weak.

In the organic electroluminescent device formed from a cathode having a surface structure of a cathode having an electron injection layer, which was obtained by depositing a zinc-electroplated film thereon by a plating treatment for 20 seconds, as shown by the microscopic photographs of FIGS. 5G and 5H, and having a surface state where several acicular deposits were piled up on the cathode surface by a zinc electroplating treatment, favorable light emission could not be confirmed. Also, the separation at an interface between the cathode 7 having the electron injection layer on the surface thereof and the organic layer was easily caused, and nonetheless the organic layer and the cathode having an electron injection layer on the surface thereof were heat and pressure bonded to each other, it was confirmed that the bond strength was extremely weak.

As shown in FIG. 5D, in view of the fact that granular particles with a diameter of not more than 100 nm serving as the electron injection layer 6, which are deposited on the surface of the cathode 7 by a zinc electroplating treatment for 5 seconds, are scatteredly deposited as shown in the photograph, the contact area between the cathode 7 including the electron injection layer and the organic layer can be increased, and an electron can be efficiently injected into the organic layer from the cathode 7. Therefore, it may be considered that the efficiency of the organic device can be enhanced.

Also, in view of the fact that when bonded to the organic layer, the shape of the bond interface is not flat, concentration or localization of a fine charge is generated, and this makes it easy to inject an electron. As a result, it may be considered that it becomes possible to realize the organic electroluminescent device 1 with high luminous efficiency.

Also, in view of the scattered covering state but not the complete covering state, all of recesses and projections of the surface of the cathode 7 are not covered by the metal oxide as a material of the electron injection layer 6, and when the cathode 7 is contact disposed on the organic layer and softened and bonded upon heating and pressurization, the softened cathode material on the surface enters fine recesses and projections of the organic surface, whereby it becomes possible to keep the bond strength.

It was revealed from FIG. 5F that the particles serving as the electron injection layer 6, which are deposited on the surface of the cathode 7 by a zinc electroplating treatment for 20 seconds, have a long and narrow shape whose length is 200 nm or more and are bulkily deposited on the surface of the cathode 7. Such bulkily deposited particles cover the entire surface of the cathode 7, and when the cathode 7 including the electron injection layer 6 is contact disposed on the organic layer and softened and bonded upon heating and pressurization, the softened cathode material on the surface cannot enter fine recesses and projections of the organic surface, whereby the bond strength becomes extremely weak.

Also, in view of the fact that the particle size is large, when the cathode 7 including the electron injection layer is brought into contact with the organic layer, the organic layer is damaged, leading to a cause of generating a short circuit between the electrodes.

As shown in FIG. 5D, when particles of the electron injection layer 6, which are deposited by zinc electroplating and which have a particle size of 50 nm or more and not more than 100 nm, are deposited and formed in the number of 5 or more and not more than 30 per unit area of 1 μm×1 μm, it becomes possible to effectively inject an electron.

As shown in FIG. 5D, particles of the electron injection layer 6, which are deposited by zinc electroplating and which have a particle size of smaller than 50 nm or exceeding 100 nm, are not the whole, but those having a particle size of smaller than 50 nm or exceeding 100 nm may be deposited so far as their amount is small.

According to this configuration, in view of the scattered covering state but not the complete covering state, even when a material having an extremely high electrical resistance value of the electron injection layer 6 is used, it is possible to realize the cathode 7 of an organic electroluminescent device capable of injecting an electron into the organic layer.

Also, in view of the fact that when bonded to the organic layer, the shape of the bond interface is not flat, concentration or localization of a fine charge is generated, and this makes it easy to inject an electron. As a result, it becomes possible to form the organic electroluminescent device 1 with high luminous efficiency.

Also, all of recesses and projections of the surface of the cathode 7 are not covered by the metal oxide as a material of the electron injection layer 6; it is possible to prevent a lowering of the bond strength between the organic layer and the electron injection layer 6 from occurring; and it is possible to secure the reliability of the organic electroluminescent device over a long period of time.

In the case where the number of particles having a particle size of 50 nm or more and not more than 100 nm per unit area is less than 5, the electron injection material having an electron injection function does not substantially exist at the bond interface with the organic layer, and when the organic electroluminescent device 1 is formed, an effective enhancement of the electron injection characteristic, namely, an enhancement of the luminous efficiency is not obtainable. Also, when the number of particles having a particle size of 50 nm or more and not more than 100 nm per unit area exceeds 30, a coverage of the electron injection layer 6 is excessively large, and the bond strength between the organic layer and the cathode having the electron injection layer on the surface thereof is remarkably lowered, whereby the reliability over a long period of time cannot be secured. Furthermore, in view of the fact that the electron injection layer 6 in the invention is made of a material having a relatively high electrical resistance value, an increase of the driving voltage of the organic electroluminescent device 1 is caused, thereby causing a lowering of the light emission life.

For example, in the organic electroluminescent device 1 prepared by performing the electroplating for a plating treatment time of 2 seconds which is shorter than 5 seconds, it was confirmed that the electron injection characteristic was not enhanced so much because particles having an electron injection function were not thoroughly deposited on the surface of the cathode 7.

On the other hand, in the organic electroluminescent device 1 prepared by performing the electroplating for a plating treatment time of 10 seconds which is longer than 5 seconds, in view of the facts that the shape of the particle having an electron injection function on the surface of the cathode 7 became large and that the coverage became large, an increase of the driving voltage was confirmed, and a result that the enhancement of the luminous efficiency was small as compared with that obtained by the electroplating for 5 seconds.

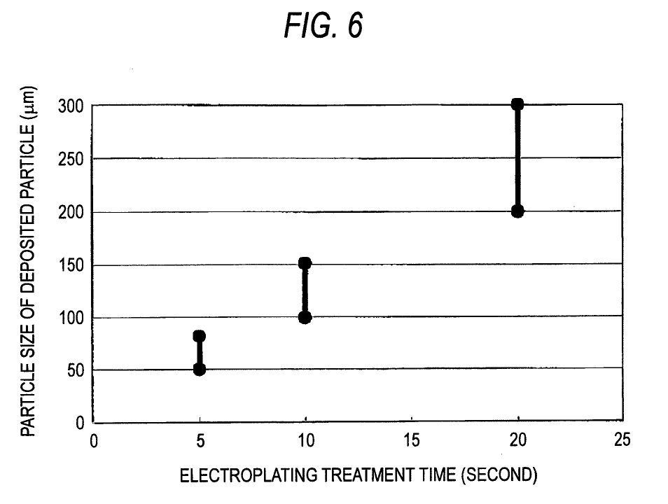

A graph obtained by plotting diameters of particles deposited on the surface of the cathode 7 versus an electroplating treatment time is shown in FIG. 6. The diameter of the majority of particles deposited when the electroplating treatment time was 5 seconds fell within the range of from 50 nm to 80 nm. Also, the diameter of the majority of particles deposited when the electroplating treatment time was 10 seconds fell within the range of from 100 nm to 150 nm. Furthermore, the diameter of the majority of particles deposited when the electroplating treatment time was 20 seconds fell within the range of from 200 nm to 300 nm. According to this, as described previously, in view of the fact that in the organic electroluminescent device obtained by the electroplating treatment for 10 seconds, the enhancement of the luminous efficiency is small as compared with that in the organic electroluminescent device obtained by the electroplating treatment for 5 seconds, it may be considered that the diameter of the majority of particles deposited on the cathode 7 is preferably in the range of from 50 nm to 150 nm, and more preferably in the range of from 50 nm to 80 nm. Also, it was understood that when the diameter of the particle becomes large exceeding 200 nm, the bond strength to the organic layer becomes extremely weak so that the light emission from the organic electroluminescent device 1 is not obtainable.

Also, in the invention, it is included that the coverage of the electron injection layer which is deposited by the foregoing plating method is 20% or more and not more than 70% per unit area relative to the surface of the cathode 7. According to this configuration, in view of the scattered covering state but not the complete covering state, even when a material having an extremely high electrical resistance value of the electron injection layer 6 is used, it is possible to realize an electrode capable of injecting an electron into the organic layer.

Also, in view of the fact that when bonded to the organic layer, the shape of the bond interface is not flat, concentration or localization of a fine charge is generated, and this makes it easy to inject an electron. As a result, it becomes possible to realize the organic electroluminescent device 1 with high luminous efficiency.

Also, all of recesses and projections of the surface of the cathode 7 are not covered by the metal oxide as a material of the electron injection layer 6; it is possible to prevent a lowering of the bond strength between the organic layer and the cathode 7 having the electron injection layer 6 from occurring; and it is possible to secure the reliability of the organic electroluminescent device over a long period of time.

In the case where the coverage is less than 20%, the electron injection material having an electron injection function does not substantially exist at the bond interface with the organic layer, and when the organic electroluminescent device 1 is formed, an effective enhancement of the electron injection characteristic, namely, an enhancement of the luminous efficiency is not obtainable. Also, when the coverage exceeds 70%, the bond strength between the organic layer and the cathode 7 is remarkably lowered, whereby the reliability over a long period of time cannot be secured. Furthermore, in view of the fact that the electron injection layer 6 in the invention is made of a material having a relatively high electrical resistance value, an increase of the driving voltage of the organic electroluminescent device 1 is caused, thereby causing a lowering of the light emission life.

The invention is concerned with an organic electroluminescent device comprising at least one light emitting layer made of an organic material between a transparent electrode and a counter electrode opposing to the transparent electrode and an electron injection layer made of a metal oxide between the light emitting layer and the counter electrode, wherein the electron injection layer is previously deposited on the counter electrode; the counter electrode is contact disposed in a solid plate form such that the electron injection layer is disposed on the side of the light emitting layer and heat and pressure formed; and the electron injection layer is deposited on the counter electrode by a plating method.

According to this configuration, it is possible to enhance the luminous efficiency of the organic electroluminescent device.

Also, by using the plating method, a high-vacuum process requiring a large amount of plant and equipment investment, such as a vapor deposition method or a sputtering method, is not required as the method of depositing an electron injection layer, and therefore, it is possible to realize a preparation process of an organic electroluminescent device which is able to significantly reduce the plant and equipment investment. As a result, it becomes possible to provide an inexpensive organic electroluminescent device.

Also, in view of the fact that by using the plating method, it is possible to exclude a vacuum step in the steps of manufacturing an organic electroluminescent device, it is possible to shorten a takt time at the time of production, and the production cost can be minimized. As a result, it becomes possible to provide an inexpensive organic electroluminescent device.

Also, as compared with the vacuum process, the plating method which is a wet deposition method is remarkably high in a deposition rate, and therefore, the treatment time is very short, and it is possible to shorten a takt time. As a result, it becomes possible to provide an inexpensive electroluminescent device.

Also, in view of the fact that the electron injection layer is constituted of a metal oxide, an electron injection layer which is inert against oxygen, moisture or the like is obtainable. In other words, it is possible to reduce influences of reactive materials in the inside and outside of the organic electroluminescent device and to obtain a stable electron injection characteristic. Also, before the counter electrode is joined with the organic layer, the electron injection layer can be previously formed on the surface of the counter electrode, whereby the electron injection layer is not formed directly on the organic layer. Thus, it becomes possible to prevent damage which is a cause of deterioration of the organic layer due to the formation of the electron injection layer. As a result, it is possible to provide an organic electroluminescent device with a long life.

Also, the invention is concerned with the foregoing organic electroluminescent device, wherein the plating method is zinc electroplating.

According to this configuration, a subject on which the electron injection layer is previously subjected to zinc electroplating is the foregoing counter electrode in a solid plate form and has high conductivity, and therefore, it is easy to obtain an electron injection layer having a uniform film thickness on the counter electrode; and when an organic electroluminescent device is formed, the injection of an electron into the organic layer from the electron injection layer is uniformly carried out, whereby it becomes possible to realize uniform light emission.

Also, in view of the fact that the plating is zinc electroplating, the plated film thickness is in proportion to an impressed electrochemical equivalent; and therefore, it is easy to control the film thickness. Also, a yield at the time of mass production is enhanced, and therefore, it is possible to provide an inexpensive organic electroluminescent device.

Also, in view of the fact that a zinc oxide film is formed by zinc electroplating, it is possible to impart an electron injection characteristic exceeding an electron injection characteristic into the organic layer to only a desired portion of the counter electrode in a solid plate form, and it is possible to enhance the luminous efficiency of the organic electroluminescent device.

Also, since zinc oxide is small in specific resistance while it is an oxide, an electric field to be impressed between the both electrodes is impressed to the light emitting layer as it is without causing a voltage drop, whereby it becomes possible to obtain a high-luminance characteristic. Also, as compared with an organic electroluminescent device using titanium oxide which is similarly a metal oxide for the electron injection layer, an organic electroluminescent device with high luminous efficiency is obtainable. Furthermore, for the deposition of titanium or titanium oxide, the formation by a plating method is difficult.

Also, since zinc oxide has an electron injection function, an electron transport function and a hole blocking function, favorable electron injection can be realized, and a light emitting region which is a region where a hole and an electron are recombined with each other in the organic layer can be controlled.

In consequence, for example, it is possible to enhance the device efficiency and further to enhance the device life by controlling the light emitting region so as to be located on the center of the light emitting layer, an aspect of which has hitherto been not easy.

Also, in view of the fact that zinc oxide is a stable material, it does not require special equipment for controlling the manufacturing environment or atmosphere, is easy for handling at the time of preparation of a device and is a general material as an oxide semiconductor material. Therefore, it is possible to provide an inexpensive organic electroluminescent device. Also, since a general plating material and a plating solution having a stable composition can be used, it is possible to provide an inexpensive organic electroluminescent device.

Also, the invention is concerned with the foregoing organic electroluminescent device, wherein the zinc electroplating is carried out dividedly twice or more.

According to this configuration, it is possible to realize uniform plating. Though the control of the film thickness of zinc electroplating is in proportion to an electrochemical equivalent, it is difficult to make the electric field distribution into a subject of plating completely uniform. Moreover, the composition of the plating bath varies with deposition of zinc, and therefore, strictly speaking, the plating condition is changed as compared with that at the initial stage. For that reason, by dividing the zinc electroplating treatment, it is possible to precisely control the film thickness.

Also, the film thickness of zinc electroplating in the invention is not more than several tens nm, the film thickness is extremely small as compared with that in general plated films, and more precise control of the film thickness is necessary. However, by dividing the zinc electroplating treatment, more precise control of the film thickness becomes possible, whereby the electron injection layer of the invention is obtained. As a result, it becomes possible to realize an organic electroluminescent device with high efficiency.

Also, the invention is concerned with the foregoing organic electroluminescent device, wherein the zinc electroplating is carried out dividedly twice or more, and a reverse voltage is impressed once or more.

According to this configuration, it is possible to realize uniform plating. Though the control of the film thickness of zinc electroplating is in proportion to an electrochemical equivalent, it is difficult to make the electric field distribution into a subject of plating completely uniform. Moreover, the composition of the plating bath varies with deposition of zinc, and therefore, strictly speaking, the plating condition is changed as compared with that at the initial stage. For that reason, by dividing the zinc electroplating treatment, it is possible to precisely control the film thickness.

Furthermore, when a reverse voltage is impressed for the purpose of relieving the concentration of an electric field, redissolution of a plated part deposited by a forward voltage occurs. As to the redissolution, the thicker the deposited portion, the more frequently the elution occurs. Thus, by properly carrying out the plating treatment by a reverse voltage, it consequently becomes possible to form a uniform zinc-electroplated film. As a yardstick of the plating treatment of the invention, it is desirable to carry out the plating treatment such that a ratio of the reverse plating to the forward plating is 1/2.

Also, the invention is concerned with the foregoing organic electroluminescent device, wherein an area of the counter electrode to be subjected to zinc electroplating falls within the range of from 1.0 to 1.6 times an area of a non-plated electrode.

According to this configuration, it is possible to realize uniform plating. As described previously, though the control of the film thickness of zinc electroplating is in proportion to an electrochemical equivalent, on that occasion, by making an area of the counter electrode to be subjected to zinc electroplating fall within the range of from 1.0 to 1.6 times an area of a non-plated electrode, it is possible to enhance the uniformity of the electric field distribution. On the contrary, when the non-plated area falls outside the foregoing range and is equal to or less or excessively large, the electric field concentration into the end occurs, whereby a non-uniform plated film is formed. According to this, in view of the fact that the uniformity of the electric field distribution is enhanced, it is possible to realize uniform plating, and as a result, it becomes possible to realize an organic electroluminescent device capable of achieving uniform light emission without causing light emission unevenness.

Also, the invention is concerned with the foregoing organic electroluminescent device, wherein the deposition is carried out by zinc electroless zinc as the plating method.

According to this configuration, even in the case where the conductivity of the counter electrode is low so that zinc electroplating is relatively difficultly applied thereto, or in the case where the counter electrode has a complicated shape so that its design and disposition are difficult, it is possible to obtain a plated film having a uniform film thickness, and as a result, it becomes possible to realize an organic electroluminescent device capable of achieving uniform light emission without causing light emission unevenness.

Also, the invention is concerned with the foregoing organic electroluminescent device, wherein after the plating treatment, the electron injection layer is naturally oxidized in a bath or the atmosphere.

According to this configuration, in view of the fact that after the plating treatment, zinc deposited on the counter electrode is naturally oxidized in a bath or the atmosphere, a desired metal oxide is obtainable without performing a special oxidization treatment, and therefore, handling is very easy. Also, it is possible to perform the deposition treatment in a usual environment or a usual atmosphere, and as a result, it becomes possible to simplify the manufacturing steps.

Also, when the deposited zinc is oxidized, an electron injection characteristic is revealed, it is possible to impart the electron injection characteristic to the counter electrode, and it is possible to enhance the luminous efficiency of the organic electroluminescent device.

Also, when the deposited zinc is oxidized, the electron injection layer has a transmittance of 80% or more; and light emitted in the organic layer and light which has passed through the organic layer and reached the electron injection layer reach the counter electrode without being absorbed in the electron injection layer, and these lights are further reflected by the counter electrode, whereby they can be again emitted outside the organic electroluminescent device through the electron injection layer, the organic layer, the transparent electrode and the substrate. Thus, it becomes possible to suppress a reduction of the light emission emitted from the organic layer.

Also, the invention is concerned with the foregoing organic electroluminescent device, wherein the electron injection layer deposited by the plating method is formed by granular deposits in a non-covering state or scatteredly relative to the counter electrode.

According to this configuration, in view of the fact that the electron injection layer is granular, the contact area between the counter electrode and the organic layer can be increased, and an electron can be efficiently injected into the organic layer from the cathode. Therefore, the efficiency of the organic device can be enhanced.

Also, in view of the scattered covering state but not the complete covering state, even when a material having an extremely high electrical resistance value of the electron injection layer is used, it is possible to realize an electrode capable of injecting an electron into the organic layer.

Also, in view of the fact that when bonded to the organic layer, the shape of the bond interface is not flat, concentration or localization of a fine charge is generated, and this makes it easy to inject an electron. As a result, it becomes possible to realize an organic electroluminescent device with high luminous efficiency.

Also, all of recesses and projections of the surface of the counter electrode are not covered by the metal oxide as a material of the electron injection layer; it is possible to prevent a lowering of the bond strength between the organic layer and the counter electrode from occurring; and it is possible to secure the reliability of the counter electrode over a long period of time.

Also, the invention is concerned with the organic electroluminescent device, wherein the electron injection layer deposited by the plating method has a particle size of not more than 100 nm.

According to this configuration, when the counter electrode in a solid plate form having the electron injection layer previously formed thereon is brought into contact with the organic layer, not only it is possible to reduce damage against the organic layer, but it is possible to form an electrode without generating a short circuit between the electrodes.

Also, the uniformity of the film thickness of the organic layer is not impaired at the time of forming an electrode, and the local electric field concentration is prevented from occurring, whereby it becomes possible to realize an organic electroluminescent device capable of achieving uniform light emission.

Also, the invention is concerned with the foregoing organic electroluminescent device, wherein the electron injection layer deposited by the plating method is formed by depositing particles having a particle size of 50 nm or more and not more than 100 nm in the number of 5 or more and not more than 30 per unit area of 1 μm×1 μm,

According to this configuration, in view of the scattered covering state but not the complete covering state, even when a material having an extremely high electrical resistance value of the electron injection layer is used, it is possible to realize an electrode capable of injecting an electron into the organic layer.

Also, in view of the fact that when bonded to the organic layer, the shape of the bond interface is not flat, concentration or localization of a fine charge is generated, and this makes it easy to inject an electron. As a result, it becomes possible to realize an organic electroluminescent device with high luminous efficiency.

Also, all of recesses and projections of the surface of the counter electrode are not covered by the metal oxide as a material of the electron injection layer; it is possible to prevent a lowering of the bond strength between the organic layer and the counter electrode from occurring; and it is possible to secure the reliability of the counter electrode over a long period of time.

In the case where the number of particles having a particle size of 50 nm or more and not more than 100 nm per unit area is less than 5, the electron injection material having an electron injection function does not substantially exist at the bond interface with the organic layer, and when an organic electroluminescent device is formed, an effective enhancement of the electron injection characteristic, namely, an enhancement of the luminous efficiency is not obtainable. Also, when the number of particles having a particle size of 50 nm or more and not more than 100 nm per unit area exceeds 30, a coverage of the electron injection layer is excessively large, and the bond strength between the organic layer and the counter electrode is remarkably lowered, whereby the reliability over a long period of time cannot be secured. Furthermore, in view of the fact that the electron injection layer in the invention is made of a material having a relatively high electrical resistance value, an increase of the driving voltage of an organic electroluminescent device is caused, thereby causing a lowering of the light emission life.

Also, the invention is concerned with the foregoing organic electroluminescent device, wherein a coverage of the electron injection layer deposited by the plating method is 20% or more and not more than 70% per unit area relative to the counter electrode.

According to this configuration, in view of the scattered covering state but not the complete covering state, even when a material having an extremely high electrical resistance value of the electron injection layer is used, it is possible to realize an electrode capable of injecting an electron into the organic layer.

Also, in view of the fact that when bonded to the organic layer, the shape of the bond interface is not flat, concentration or localization of a fine charge is generated, and this makes it easy to inject an electron. As a result, it becomes possible to realize an organic electroluminescent device with high luminous efficiency.

Also, all of recesses and projections of the surface of the counter electrode are not covered by the metal oxide as a material of the electron injection layer; it is possible to prevent a lowering of the bond strength between the organic layer and the counter electrode from occurring; and it is possible to secure the reliability of the counter electrode over a long period of time.

In the case where the coverage is less than 20%, the electron injection material having an electron injection function does not substantially exist at the bond interface with the organic layer, and when an organic electroluminescent device is formed, an effective enhancement of the electron injection characteristic, namely, an enhancement of the luminous efficiency is not obtainable. Also, when the coverage exceeds 70%, the bond strength between the organic layer and the counter electrode is remarkably lowered, whereby the reliability over a long period of time cannot be secured. Furthermore, in view of the fact that the electron injection layer in the invention is made of a material having a relatively high electrical resistance value, an increase of the driving voltage of an organic electroluminescent device is caused, thereby causing a lowering of the light emission life.

The invention is concerned with an organic electroluminescent device and a method for manufacturing the same and also with an organic device which is prepared so as to have a configuration of two or more electrodes and an organic layer. In particular, the invention is useful for display devices and electronic appliances using an organic electroluminescent device as a light source.

This application claims the benefit of Japanese Patent application No. 2009-096856 filed on Apr. 13, 2009, Japanese Patent application No. 2009-239022 filed on Oct. 16, 2009, the entire contents of which are incorporated herein by reference.

1. An organic electroluminescent device, comprising:
a transparent electrode;
a counter electrode that is opposed to the transparent electrode; and
a light emitting layer made of an organic material;
wherein the light emitting layer is provided between the transparent electrode and the counter electrode;
the light emitting layer includes an electron injection layer provided between the light emitting layer and the counter electrode; and
the electron injection layer is constituted of a metal oxide.

2. The organic electroluminescent device according to claim 1, wherein the metal oxide is zinc oxide (ZnO) and titanium oxide (TiO₂).

3. The organic electroluminescent device according to claim 1, wherein the counter electrode in a solid plate form has a thickness of 5 μm or more.

4. The organic electroluminescent device according to claim 1, wherein the electron injection layer has a film thickness of from 10 angstroms to 200 angstroms.

5. The organic electroluminescent device according to claim 4, wherein the electron injection layer has a film thickness of from 60 angstroms to 100 angstroms.

6. The organic electroluminescent device according to claim 1, wherein the electron injection layer has a transmittance of 80% or more relative to light emitted from the organic layer and light passing through the organic layer.

7. The organic electroluminescent device according to claim 1, wherein the electron injection layer has a specific resistance of not more than 10,000 Ωm.

8. The organic electroluminescent device according to claim 1, wherein the electron injection layer has a work function of from 4.0 eV to 6.0 eV.

9. The organic electroluminescent device according to claim 1, wherein an average surface roughness Ra of the surface of the counter electrode on which the electron injection layer is provided is thicker than a film thickness of the electron injection layer.

10. The organic electroluminescent device according to claim 1, wherein an average surface roughness Ra of the surface of the counter electrode on which the electron injection is provided is smaller than the total sum of a film thickness of the organic layer existing between the two electrodes counterpart to each other.

11. The organic electroluminescent device according to claim 1, wherein an average surface roughness Ra of the surface of the counter electrode on which the electron injection layer is provided is from 20 nm to 300 nm.

12. The organic electroluminescent device according to claim 1, wherein the at least one organic layer includes a layer made of a conductive polymer material.

13. The organic electroluminescent device according to claim 1, wherein the at least one organic layer is deposited by a coating method.

14. A manufacturing method for the organic electroluminescent device according to claim 1, comprising steps of:
forming the light emitting layer at a side of the transparent electrode;
forming the electron injection layer at a side of the counter electrode;
disposing the counter electrode so that the electron injection layer is provided at a side of the light emitting layer; and
heating and applying a load between the transparent electrode and the counter electrode.

15. The manufacturing method according to claim 14, wherein the electron
injection layer is deposited on the counter electrode by a plating method.

16. A light emitting device wherein a current and a voltage are fed to the transparent electrode and the counter electrode according to claim 1 through a conductive material connected to an external control circuit, thereby controlling light emission.

17. A display device comprising the light emitting device and the display device according to claim 14 as a light source and using for a backlight.

18. An electronic appliance comprising a display part using, as a light source, the light emitting device and the display device according to claim 14.

19. An organic electroluminescent device, comprising:
at least one light emitting layer made of an organic material between a transparent electrode and a counter electrode opposing to the transparent electrode and an electron injection layer made of a metal oxide between the light emitting layer and the counter electrode, wherein the electron injection layer is previously deposited on the counter electrode; the counter electrode is contact disposed in a solid plate form such that the electron injection layer is disposed on the side of the light emitting layer and heat and pressure formed; and the electron injection layer is deposited on the counter electrode by a plating method.

20. The organic electroluminescent device according to claim 19, wherein the electron injection layer deposited by the plating method has a particle size of not more than 100 nm.
